(19) United States
(12) Patent Application Publication
(10) Pub. No.: US 2021/0320006 A1
(43) Pub. Date: Oct. 14, 2021

(54) METHOD OF MANUFACTURING A SEMICONDUCTOR COMPONENT, AND WORKPIECE

(71) Applicant: OSRAM OLED GmbH, Regensburg (DE)

(72) Inventors: Martin Behringer, Regensburg (DE); Alexander Behres, Pfatter (DE); Asako Hirai, Regensburg (DE)

(21) Appl. No.: 17/267,307

(22) PCT Filed: Aug. 9, 2019
(86) PCT No.: PCT/EP2019/071496

§ 371 Date: Feb. 9, 2021

(30) Foreign Application Priority Data
Aug. 13, 2018 (DE) 10 2018 119 634.2

(51) Int. Cl. H01L 21/02; H01L 21/683; H01L 23/00

(52) U.S. Cl. CPC H01L 21/02634; H01L 2924/20106; H01L 21/6835; H01L 21/02505; H01L 21/02598; H01L 21/02513; H01L 24/83; H01L 2221/6835; H01L 2221/68368; H01L 21/02458; H01L 21/0242; H01L 21/02499; H01L 2224/83099; H01L 2924/20102; H01L 2224/83896; H01L 2224/83193; H01L 2224/83026; H01L 21/0254

(57) ABSTRACT

A method for producing a semiconductor component and workpiece are disclosed. In an embodiment a method includes forming a first semiconductor layer over a growth substrate, wherein a material of the first semiconductor layer is Inₓ₁Al_{y1}Ga_{(1-x1-y1)}N, with 0≤xl≤1, 0≤yl≤1, applying a first modification substrate over the first semiconductor layer, wherein a material of the first modification substrate has a thermal expansion coefficient which is different from that of the first semiconductor layer, removing the growth substrate thereby obtaining a first layer stack, heating the first layer stack to a first growth temperature and growing a second semiconductor layer over a growth surface of the first semiconductor layer after heating the first layer stack, wherein due to heating a lattice constant of the first semiconductor layer is adapted to a lattice constant of the second semiconductor layer.

This patent application is a national phase filing under section 371 of PCT/EP2019/071496, filed Aug. 9, 2019, which claims the priority of German patent application 102018119634.2, filed Aug. 13, 2018, each of which is incorporated herein by reference in its entirety.

### BACKGROUND

In the production of semiconductor devices, for example, optoelectronic semiconductor devices, semiconductor layers are usually grown epitaxially on a monocrystalline or single-crystal substrate. Efforts are being made to form semiconductor layers with a freely selectable lattice constant and good crystal quality.

### SUMMARY OF THE INVENTION

Embodiments provide an improved method for producing a semiconductor device and a corresponding workpiece.

According to embodiments, a method for producing a semiconductor device comprises forming a first semiconductor layer over a growth substrate and applying a modification substrate over the first semiconductor layer, wherein a material of the modification substrate has a thermal expansion coefficient which is different from that of the semiconductor layer. The growth substrate is removed, thereby obtaining a first layer stack. The first layer stack is then heated to a growth temperature.

The method may further comprise growing a second semiconductor layer over a growth surface of the first semiconductor layer after heating the first layer stack. For example, a growth surface is a surface of the first semiconductor layer facing the growth substrate.

According to further embodiments, the method may further comprise applying an intermediate substrate over the first semiconductor layer before applying the modification substrate. Here, the intermediate substrate is removed after removing the growth substrate and after applying the modification substrate. In this case, a growth surface may, for example, be a surface of the first semiconductor layer facing the second substrate.

A material of the second semiconductor layer may be different from a material of the first semiconductor layer. For example, the elements of the first and second semiconductor layers may each be identical, and the stoichiometric ratio may vary.

For example, the material of the first semiconductor layer may be Inₓ₁Al_{y1}Ga_{(1-x1-y1)}N. The material of the second semiconductor layer may be Inₓ₂Al_{y2}Ga_{(1-x2-y2)}N, with x1≠x2, y1≠y2. In general, 0<x1<1 and 0<y1<1. Furthermore, x1+y1<1, x2+y2<1.

The modification substrate may be applied at room temperature. In particular, the term “room temperature” means a temperature range which is lower than a temperature that prevails when layers are grown. For example, the temperature range may be less than 100° C. and extend from 20° C. to 25° C.

The formation of the first semiconductor layer may include epitaxial growth.

According to embodiments, the formation of the first semiconductor layer may comprise the formation of a separating layer between two substrate parts.

According to embodiments, the method may further comprise forming a third semiconductor layer over the second semiconductor layer, applying a carrier material over the third semiconductor layer and removing the first layer stack and the second semiconductor layer. A modification substrate is applied over the third semiconductor layer, wherein a material of the modification substrate has a thermal expansion coefficient which is different from that of the third semiconductor layer. The carrier material is removed, thereby obtaining a second layer stack. The second layer stack is then heated to a growth temperature, and a fourth semiconductor layer is grown.

According to embodiments, a workpiece includes a modification substrate and a first single-crystal semiconductor layer over the modification substrate. In this case, a material of the modification substrate has a thermal expansion coefficient which is different from that of the first single-crystal semiconductor layer.

The workpiece may furthermore include a second single-crystal semiconductor layer over the first single-crystal semiconductor layer, wherein a composition of the first single-crystal semiconductor layer is different from the composition of the second single-crystal semiconductor layer. For example, the elements of the first and second semiconductor layers may each be identical and the stoichiometric ratio may vary.

The material of the first semiconductor layer may be Inₓ₁Al_{y1}Ga_{(1-x1-y1)}N. The material of the second semiconductor layer may be Inₓ₂Al_{y2}Ga_{(1-x2-y2)}N, with x1≠x2, y1≠y2.

### BRIEF DESCRIPTION OF THE DRAWINGS

The accompanying drawings serve to provide an understanding of exemplary embodiments of the invention. The drawings illustrate exemplary embodiments and, together with the description, serve to explain them. Further exemplary embodiments and many of the intended advantages will become apparent directly from the following detailed description. The elements and structures shown in the drawings are not necessarily shown to scale relative to each another. Like reference numerals refer to like or corresponding elements and structures.

FIGS. 1A to ID illustrate cross-sectional views of a workpiece during performance of a method according to embodiments;

FIG. 1E shows a cross-sectional view of a workpiece after further method steps have been performed;

FIG. 1F shows a cross-sectional view of a workpiece after further method steps have been performed;

FIG. 1G shows a cross-sectional view of a workpiece after further method steps have been performed;

FIGS. 2A to 2F show cross-sectional views of a workpiece during performance of a method according to further embodiments; and

FIG. 3 outlines a method according to embodiments.

### DETAILED DESCRIPTION OF ILLUSTRATIVE EMBODIMENTS

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is only used by way of explanation and is in no way intended to be limiting.

The description of the exemplary embodiments is not limiting, since there are also other exemplary embodiments and structural or logical changes may be made without departing from the scope as defined by the patent claims. In particular, elements of the exemplary embodiments described below may be combined with elements from others of the exemplary embodiments described, unless the context indicates otherwise.

The semiconductor materials described here may be semiconductor materials having a direct or an indirect band gap, depending on the intended use. Examples of semiconductor materials particularly suitable for generating electromagnetic radiation include, without limitation, nitride semiconductor compounds, by means of which, for example, ultraviolet, blue or long-wave light may be generated, such as GaN, InGaN, AlN, AlGaN, AlGaInN, phosphide semiconductor compounds by means of which, for example, green or longer-wave light may be generated, such as GaAsP, AlGalnP, GaP, AlGaP, and other semiconductor materials such as AlGaAs, SiC, ZnSe, GaAs, ZnO, Ga₂O₃, diamond, hexagonal BN, and combinations of the materials mentioned. The stoichiometric ratio of the ternary compounds may vary. Other examples of semiconductor materials may include silicon, silicon germanium, and germanium.

The term “substrate” generally includes insulating, conductive or semiconductor substrates. According to embodiments, a suitable substrate material is selected such that it is suitable for the process steps described.

The terms “lateral” and “horizontal”, as used in this description, are intended to describe an orientation or alignment which runs essentially parallel to a first surface of a substrate or semiconductor body. This may, for example, be the surface of a wafer or a chip (die).

The horizontal direction may, for example, lie in a plane perpendicular to a direction of growth when layers are grown.

The term “vertical”, as used in this description, is intended to describe an orientation which is essentially perpendicular to the first surface of a substrate or semiconductor body. The vertical direction may correspond, for example, to a direction of growth when layers are grown.

In the context of the present application, the designation “over” in connection with applied layers refers to a distance from a base layer, for example a substrate, on which the individual layers are applied. For example, the feature of a first layer being arranged “over” a second layer means that the first layer is at a greater distance from the base layer than the second layer.

To the extent used herein, the terms “have”, “contain”, “comprise”, and the like are open-ended terms that indicate the presence of said elements or features, but do not exclude the presence of further elements or features. The indefinite articles and the definite articles include both the plural and the singular, unless the context clearly indicates otherwise.

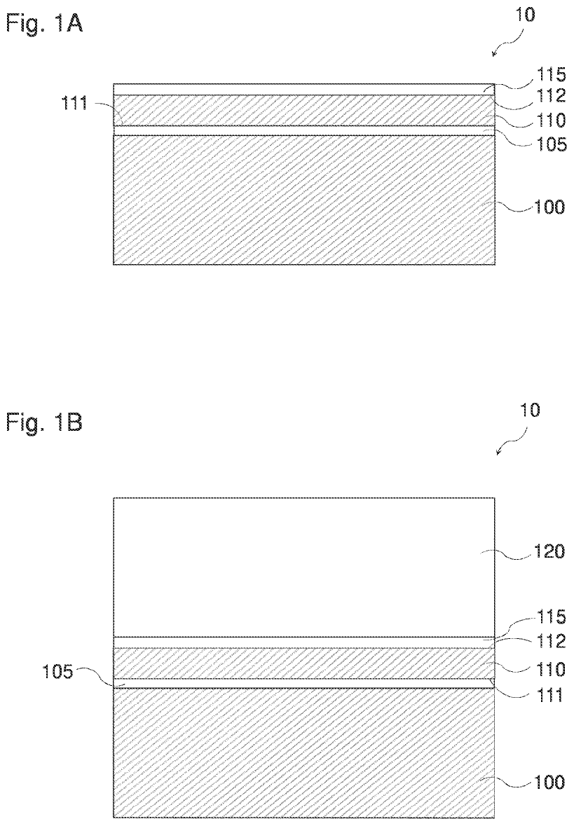

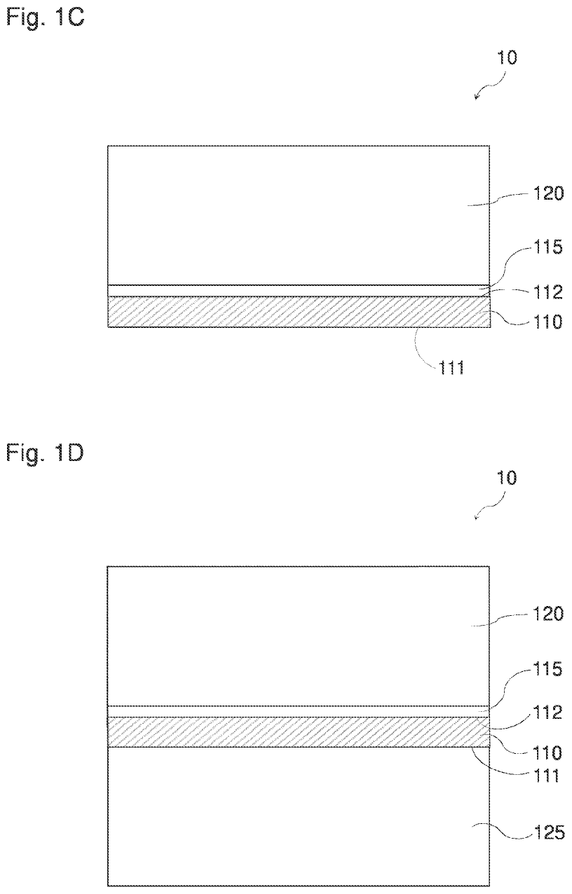

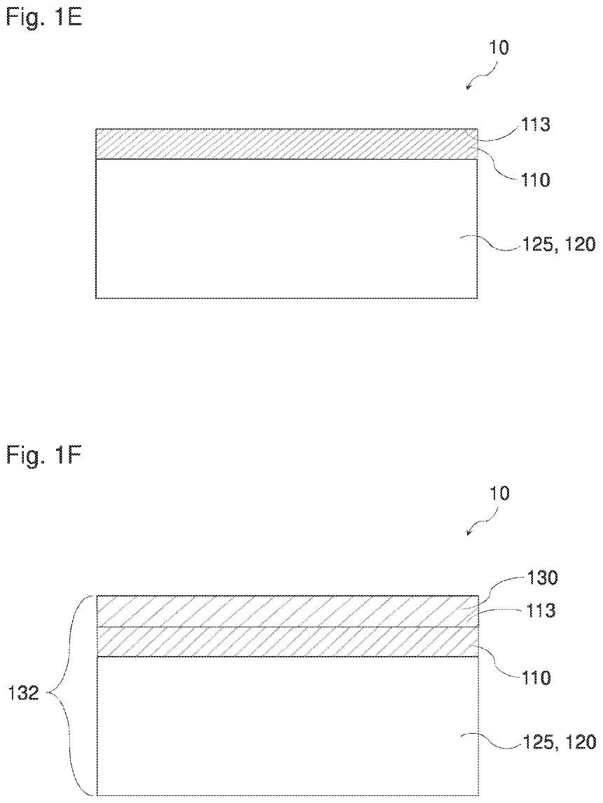

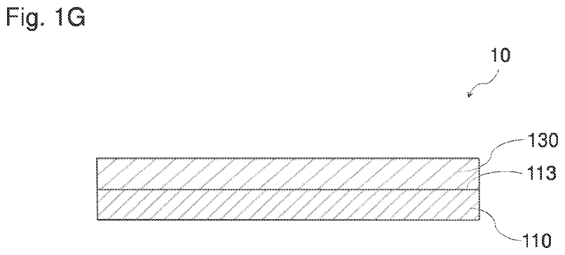

FIG. 1A shows a cross-sectional view of a workpiece 10 during performance of a method according to embodiments. A first semiconductor layer no is formed over a growth substrate 100. For example, the first semiconductor layer may be an InₓAl_{y}Ga_{(1-x-y)}N layer. The growth substrate 100 may, for example, be a GaN substrate or a so-called “free-standing” GaN layer. This may have been produced, for example, by growing a GaN layer on a suitable substrate and then removing the substrate. The composition of the InₓAl_{y}Ga_{(1-x-y)}N layer may, for example, be selected such that the lattice constant of the InₓAl_{y}Ga_{(1-x-y)}N layer is very similar to the lattice constant of the GaN layer, so that the InₓAl_{y}Ga_{(1-x-y)}N layer has good crystal quality. The first semiconductor layer no should have as few defects as possible. The layer thickness of the first semiconductor layer no may be selected so as to enable the first semiconductor layer no to be produced with a low defect rate.

A separating layer 105 may, for example, be arranged between the first semiconductor layer no and the growth substrate 100. Examples of the separating layer comprise, for example, an underetchable metal layer. The separating layer 105 may, for example, have a layer thickness of 1 to 2 monolayers, so that the lattice constant of the first semiconductor layer no is largely adapted to the lattice constant of the growth substrate 100. According to embodiments, the first separating layer 105 may first be formed on the growth substrate 100, followed by epitaxial growth of the first semiconductor layer no.

According to further embodiments, the separating layer 105 may, however, also be produced by implantation in a suitable substrate. The substrate may be, for example, an InₓAl_{y}Ga_{(1-x-y)}N layer formed over a sapphire substrate. For example, hydrogen may be implanted. The depth of penetration may be adjusted by adjusting the energy of the hydrogen atoms. In this case, by introducing the separation layer, the first semiconductor layer is formed over a growth substrate.

According to further embodiments, the separating layer 105 may be omitted. In a later process stage, the first semiconductor layer may be detached from the growth substrate by means of a laser lift-off process.

A second main surface 111 of the semiconductor layer 110 is adjacent the first separating layer 105.

According to embodiments, a second separating layer 115 may be applied over the first main surface 112 of the semiconductor layer 110. The second separating layer may be constructed, for example, similar to the first separating layer described above. The second separating layer 115 is applied in the event that a rebonding process on a third substrate 125 takes place, as will be described below with reference to FIG. 1D. According to further embodiments, the first or second separating layer may be omitted. For example, a growth or modification substrate may be removed by a laser lift-off process.

As illustrated in FIG. 1B, a second substrate 120 is subsequently applied over the semiconductor layer 110. If no rebonding process onto a third substrate 125 is provided and no second separating layer 115 is applied, the second substrate 120 is arranged directly on the first main surface 112 of the semiconductor layer 110. In this case, the second substrate 120 constitutes a modification substrate by means of which the lattice constant of a layer to be grown is modified, as will be described below.

Alternatively, a second separating layer 115 may be arranged between the first main surface 112 of the semiconductor layer 110 and the second substrate 120. If a rebonding process takes place later, the second substrate 120 constitutes an intermediate substrate which will be removed after the rebonding process onto the modification substrate.

The application of the second substrate may be carried out at room temperature (25° C.) or at a temperature which is lower than a temperature for epitaxial growth of semiconductor layers.

The second substrate 120 may be applied, for example, by a rebonding process. For example, a thin SiO₂ or Si layer with a perfectly smooth surface may be applied on the surface of the workpiece shown in FIG. 1A that faces away from the growth substrate 100. A perfectly smooth SiO₂ or Si layer is also applied to the side of the second substrate 120 facing the semiconductor layer 110. In this context, the term “perfectly smooth surface” means that deviations of the surface from a center line are only permissible within the nanometer range.

This is followed by activation, through which respective OH groups are formed on the surface of workpiece 10 and the second substrate 120. The two parts are joined together, the hydrogen atom from the second substrate 120 being replaced by the Si atom of the surface of the workpiece 10 or vice versa. This may then be followed by heating up to around 200° C., thereby effecting solidification and allowing hydrogen to be expelled. This rebonding may, for example, be carried out without organic solvents.

Another method of joining the second substrate 120 and workpiece 10 may be used as well. It should be noted here that the connection between the second substrate 120 and the workpiece 10 remains intact even at high temperatures. Furthermore, the growth chamber should not be contaminated by outgassing during the joining process.

The second substrate 120 may be a modification substrate, i.e., a substrate through which the lattice constant of a layer to be applied may be modified. In this case, a material of the second substrate 120 may have a thermal expansion coefficient that is different from the thermal expansion coefficient of the first semiconductor layer no. For example, the temperature-dependent expansion coefficient may be greater than that of the semiconductor layer 110. If, for example, gallium nitride is the base material of the semiconductor layer 110, then sapphire may be used as the second substrate 120. This is advantageous, for example, if the semiconductor layer to be grown has a higher indium content than the semiconductor layer 110, because the addition of indium increases the lattice constant of gallium nitride. Conversely, if, for example, the content of aluminum is increased compared to the semiconductor layer 110, a substrate with a smaller thermal expansion coefficient than that of the first semiconductor layer 110 may be used. In this case, for example, silicon oxide or silicon may be used. By changing the Al or In content, the band gap of the semiconductor material may be altered. In an application for optoelectronic semiconductor devices, by altering the band gap, the wavelength of the emitted or absorbed light may be adjusted.

When considering the thermal expansion coefficient, the behavior of the expansion coefficient in a temperature range from room temperature to the growth temperature of the semiconductor layers to be applied is relevant. For example, gallium nitride has a temperature-dependent expansion coefficient of 6 ppm. In contrast, silicon oxide, for example, has 2 ppm, silicon has an expansion coefficient of, for example, 2.5 ppm.

Then the growth substrate 100 is peeled off the workpiece, as illustrated in FIG. 1C. This may, for example, be carried out by a laser lift-off method or by detaching or destroying the first separating layer 105. According to further embodiments, this may also be carried out by cleaving, by detaching at the first separating layer 105 or by separating at a layer made separable by implantation.

If necessary, rebonding onto a third substrate 125, which then constitutes the modification substrate, may then be carried out. Such a rebonding process maintains the polarity on the surface of the semiconductor layer no during the growth process. In other words, if the method were carried out without rebonding onto the third substrate 125, the second main surface 111 of the semiconductor layer 110 would become the growth surface 113 of the workpiece. By using a third substrate 125, the first main surface 112 may be maintained as the growth surface 113 during the subsequent epitaxial growth of a further semiconductor layer. When using the third substrate 125, the second substrate 120, i.e., the intermediate substrate, may be selected arbitrarily. In particular, the thermal expansion coefficient may—in contrast to what has been described above—be selected arbitrarily. In this case, the material of the third substrate 125, i.e., the modification substrate, has a thermal expansion coefficient which, as described above, is different from the thermal expansion coefficient of the semiconductor layer 110.

The rebonding onto the third substrate 125 may be carried out in a manner analogous to that described above with respect to the second substrate 120. Furthermore, the intermediate substrate or second substrate 120 is removed from the surface 112 of the semiconductor layer 110. This may be carried out in a manner analogous to that described above with reference to the growth substrate 100.

FIG. 1E shows a cross-sectional view of a resulting workpiece 10. The semiconductor layer 110 is arranged over the modification substrate, i.e., the third substrate 125 or the second substrate 120. Depending on whether or not a rebonding process has previously been carried out on the third substrate 125, an N phase or a Ga phase is now present on the growth surface 113.

If necessary, the growth surface 113 may now be prepared in such a way that it is suitable for a subsequent epitaxial growth. This may comprise, for example, a cleaning process or oxidation and subsequent etching away of the oxide layer produced. Furthermore, the upper surface may be polished and a thin surface layer may be removed by etching.

FIG. 1E shows a workpiece 10 according to embodiments. A workpiece 10 comprises a modification substrate 120, 125 and a first single-crystal semiconductor layer 110 over the modification substrate. A material of the modification substrate 120, 125 has a thermal expansion coefficient that is different from that of the semiconductor layer.

The workpiece 10 is introduced into a system for epitaxial growth, for example. The workpiece is then heated to a growth temperature. When heating up, the second or third substrate 120, 125, i.e., the modification substrate, expands to a different extent than the semiconductor layer 110, thereby changing the crystal lattice of the semiconductor layer 110 accordingly. For example, it expands more when sapphire or a material that has a greater expansion coefficient than the semiconductor layer 100 is used. As a result, the crystal lattice of the semiconductor layer no is expanded to a greater extent than if the semiconductor layer were expanded without a modification substrate.

After the heating process has been carried out, the semiconductor layer 110a has a greater lattice constant when the growth temperature is reached than in the relaxed state. If a further semiconductor layer with a larger lattice constant is then epitaxially grown, this may be applied with better crystal quality than if it were applied to a semiconductor layer no without an extended lattice constant. The lattice constant of the semiconductor layer 110a is thus adapted the lattice constant of the layer to be grown. In a corresponding manner, when using a substrate with smaller thermal expansion coefficient—compared to the thermal expansion coefficient of the semiconductor layer 110—, the lattice constant of the layer 110a is reduced.

The growth temperature may be more than 700° C., for example about 750° C. As illustrated in FIG. 1F, a second semiconductor layer 130 is then grown over the growth surface 113 of the semiconductor layer 110a. As discussed above, because the lattice constant of layer 110a is adapted to the lattice constant of the layer 130 to be grown, the semiconductor layer 130 may be grown with improved crystal quality. According to further embodiments, the In or Al content may be increased further, so that a higher In or Al content may be achieved with the crystal quality remaining the same. For example, by using the method workflow described in FIGS. 1A to 1F, the In or Al content may be increased by 2 to 10%, for example 2 to 3% or more.

For example, the second semiconductor layer may be applied with a layer thickness of less than 100 nm or even less than 10 nm.

In general, the material of the modification substrate 120, 125 is selected according to whether the material of the second semiconductor layer 130 has a larger or smaller lattice constant than the first semiconductor layer 110.

FIG. 1F shows a workpiece 10 according to further embodiments. The workpiece 10 may furthermore comprise a second single-crystal semiconductor layer 130 over the first single-crystal semiconductor layer, a composition of the first single-crystal semiconductor layer 110 being different from the composition of the second single-crystal semiconductor layer 130.

According to embodiments, the modification substrate 125, 120 may then be removed. FIG. 1G shows a workpiece 10 according to embodiments. The workpiece comprises a second single-crystal semiconductor layer 130 over the first single-crystal semiconductor layer, a composition of the first single-crystal semiconductor layer no being different from the composition of the second single-crystal semiconductor layer 130.

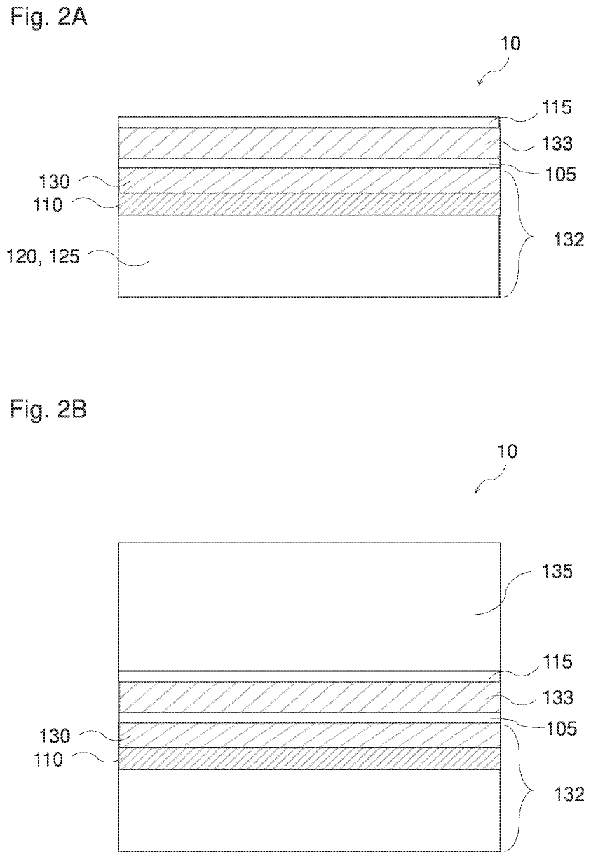

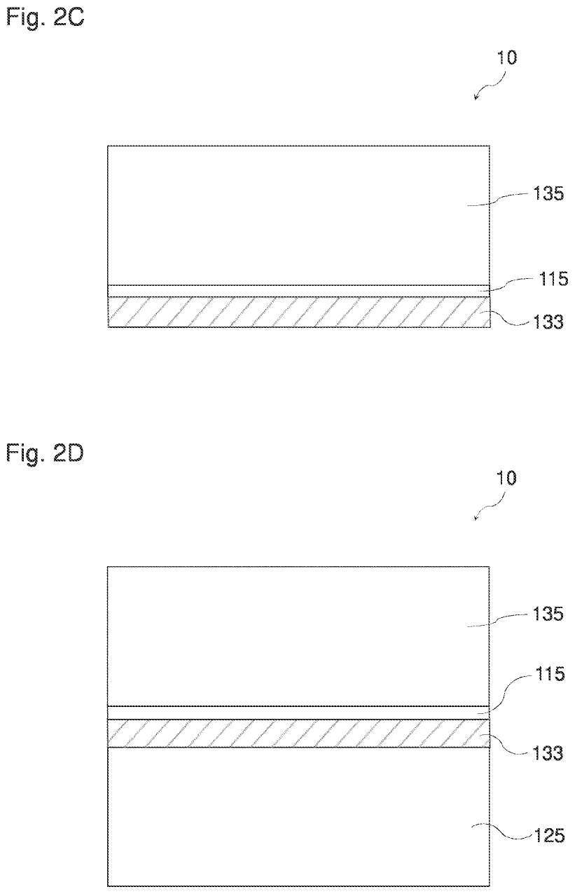

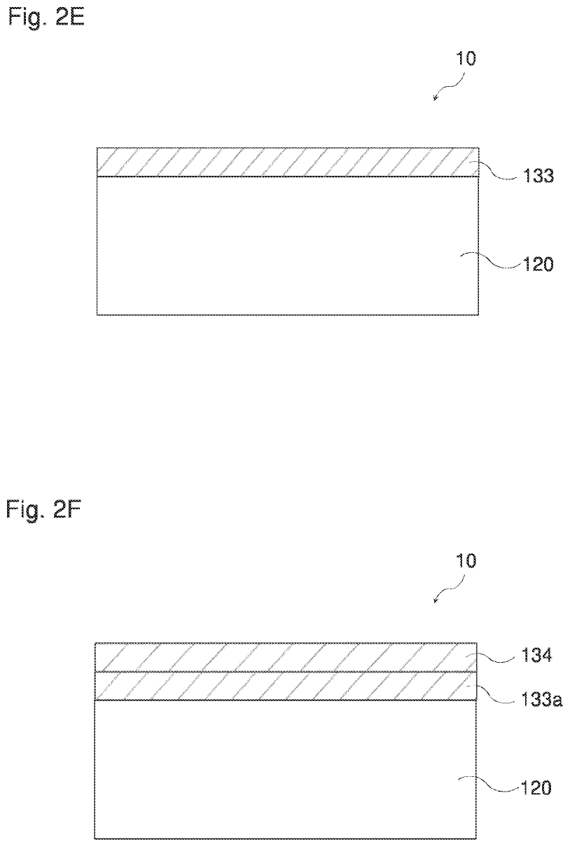

According to further embodiments, as depicted in FIGS. 2A to 2F, the method described may be repeated, in order to further adapt and change the lattice constant and thus the Al or In content. For example, starting from the first workpiece 132 depicted in FIG. 1F, again a first separating layer 105, a third semiconductor layer 133 and a second separating layer 115 are first applied to the second semiconductor layer 130 as has been described above with reference to FIG. 1A. The lattice constant and thus the composition of the third semiconductor layer are selected such that the lattice constant of the third semiconductor layer 133 is adapted to that of the second semiconductor layer 130. FIG. 2A shows a cross-sectional view of a resulting workpiece.

A carrier element 135 is then applied over the second release layer 115, as shown in FIG. 2B. The carrier material 135 may, for example, contain one of the aforementioned materials. In this case, for example, the rebonding onto the carrier material 135 may be carried out with an adhesive which flexibly allows the tension to be released from the layer stack after the first workpiece 132 has been removed. BCB (benzocyclobutene) may be used as a relaxing adhesive. According to further embodiments, the rebonding may alternatively be carried out onto a flexible carrier material 135. As the flexible carrier material, a film or a polymer may be used, for example a soft plastic slab, which is easier to shape than a semiconductor material.

Subsequently, the layers of the first workpiece 132 are removed as illustrated in FIG. 2C. This may be done in a manner similar to that described with reference to FIG. 1C. As the carrier material is flexible or a relaxing adhesive is used, the third semiconductor layer 133 may relax.

Then the workpiece depicted in FIG. 2C is rebonded onto a third substrate 125 as a modification substrate, as described above with reference to FIG. 1D. FIG. 2D shows a cross-sectional view of the resulting workpiece.

FIG. 2E shows a cross-sectional view of the workpiece after the carrier material 135 has been detached. After the carrier material 135 has been detached, the heating process may be carried out again, thereby allowing for the lattice constant of the semiconductor layer 133 to be increased further and the modified semiconductor layer 133a to form. Next, as described with reference to FIG. 1F, the fourth semiconductor layer 134 is epitaxially grown as illustrated in FIG. 2F.

Again, as discussed above, by adapting the lattice constant of layer 133a to the lattice constant of the fourth semiconductor layer 134 to be grown, the fourth semiconductor layer 134 may be grown with improved crystal quality. According to further embodiments, the In or Al content may be increased further so that a higher In or Al content may be achieved while the crystal quality remains the same. Again the In or Al content may be increased, for example, by 2 to 10%, for example 2 to 3% or more.

The fourth semiconductor layer 134 may, for example, be applied with a layer thickness of less than 100 nm or even less than 10 nm.

According to further embodiments, as discussed above with reference to FIGS. 1A to 1F, the carrier material 135 itself may constitute the modification substrate and a rebonding onto the third substrate 125 may be omitted.

The workpiece produced according to embodiments may be processed further in order to produce the functionality of the semiconductor device. For example, areas of the workpiece may be patterned, further layers may be deposited and patterned, doping processes may be carried out and further processes known in the field of semiconductor technology may be carried out. For example, a semiconductor device may be an optoelectronic semiconductor device that is suitable to emit or receive electromagnetic radiation. According to further embodiments, however, the semiconductor device may have other functions.

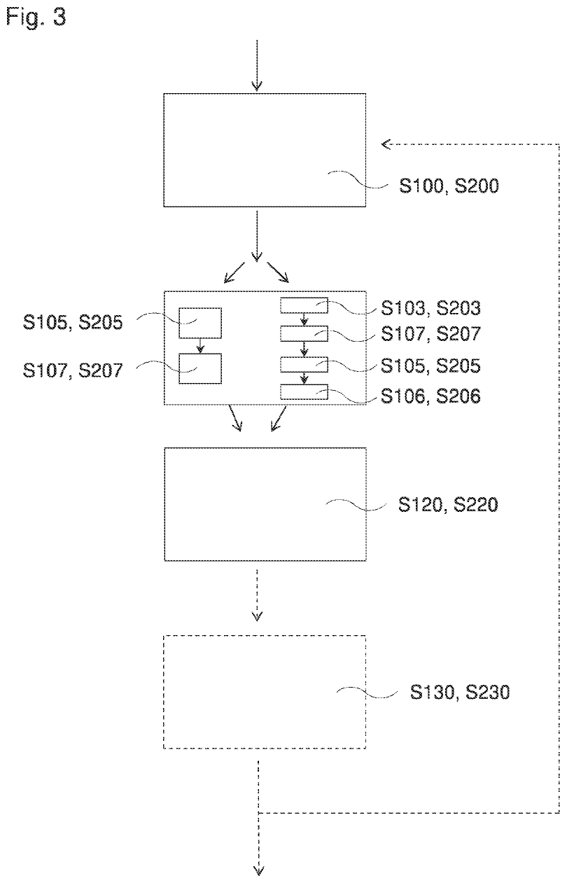

FIG. 3 outlines a method according to embodiments.

A method for producing a semiconductor device comprises forming (S100) a first semiconductor layer over a growth substrate, applying (105) a modification substrate over the first semiconductor layer, wherein a material of the second substrate has a thermal expansion coefficient which is different from that of the semiconductor layer, removing (S107) the growth substrate, thereby obtaining a first layer stack, and heating (S120) the first layer stack to a growth temperature. As shown in the left-hand part of the process flow, the modification substrate may, for example, be applied (S105) before the growth substrate is removed. For example, in this case, the second substrate 120 corresponds to the modification substrate.

According to further embodiments, however, the method may comprise applying (S103) an intermediate substrate over the first semiconductor layer. In this case, the growth substrate is removed after applying the intermediate substrate, and the modification substrate is applied after removing the growth substrate. The intermediate substrate may be removed after applying the modification substrate (S106). For example, in this case, the second substrate 120 corresponds to the intermediate substrate, and the third substrate 125 corresponds to the modification substrate.

The method may furthermore include growing (S130) a second semiconductor layer over a growth surface of the first semiconductor layer after heating the first layer stack.

According to further embodiments, the method may be repeated after the second semiconductor layer has been grown. In this case, according to embodiments, a third semiconductor layer is first formed over the second semiconductor layer (S200). The method further comprises applying (S303) a carrier material over the third semiconductor layer, removing (S207) the first layer stack and the second semiconductor layer and applying (S205) a modification substrate over the third semiconductor layer, wherein a material of the modification substrate has a thermal expansion coefficient which is different from that of the third semiconductor layer. The carrier material is then removed (S206), thereby obtaining a second layer stack. The method further comprises heating (S220) the second layer stack to a growth temperature and growing (S230) a fourth semiconductor layer.

According to further embodiments, it is possible for the carrier material itself to constitute the modification substrate. In this case, after growing the second semiconductor layer, a third semiconductor layer is first formed over the second semiconductor layer (S200). The method furthermore comprises applying (S205) a carrier material over the third semiconductor layer and removing (S207) the first layer stack and the second semiconductor layer, thereby obtaining a second layer stack. For example, the carrier material has a thermal expansion coefficient which is different from that of the third semiconductor layer. The second layer stack is then heated to a growth temperature (S220), and a fourth semiconductor layer is grown (S230).

Although specific embodiments have been illustrated and described herein, those skilled in the art will recognize that the specific embodiments shown and described may be replaced by a variety of alternative and/or equivalent configurations without departing from the scope of the invention. The application is intended to cover any adaptations or variations of the specific embodiments discussed herein. Therefore, the invention is to be limited only by the claims and their equivalents.

1.-13. (canceled)

14. A method for manufacturing a semiconductor device, the method comprising:
forming a first semiconductor layer over a growth substrate, wherein a material of the first semiconductor layer is Inₓ₁Al_{y1}Ga_{(1-x1-y1)}N, with 0≤xl≤1, 0≤yl≤1;
applying a first modification substrate over the first semiconductor layer, wherein a material of the first modification substrate has a thermal expansion coefficient which is different from that of the first semiconductor layer;
removing the growth substrate thereby obtaining a first layer stack;
heating the first layer stack to a first growth temperature; and
growing a second semiconductor layer over a growth surface of the first semiconductor layer after heating the first layer stack,
wherein due to heating a lattice constant of the first semiconductor layer is adapted to a lattice constant of the second semiconductor layer.

15. The method according to claim 14, wherein the growth surface is a surface of the first semiconductor layer facing the growth substrate.

16. The method according to claim 14, further comprising applying an intermediate substrate over the first semiconductor layer before applying the first modification substrate, wherein the intermediate substrate is removed after removing the growth substrate and after applying the first modification substrate.

17. The method according to claim 16, wherein the growth surface is a surface of the first semiconductor layer facing the intermediate substrate.

18. The method according to claim 14, wherein a material of the second semiconductor layer is different from the material of the first semiconductor layer.

19. The method according to claim 14, wherein the material of the second semiconductor layer is InₓAl_{y}Ga_{(1-x2-y)}N, with x1≠x2, y1≠y2.

20. The method according to claim 14, wherein the first modification substrate is applied at room temperature.

21. The method according to claim 14, wherein forming the first semiconductor layer comprises epitaxially growing the first semiconductor layer.

22. The method according to claim 14, wherein forming the first semiconductor layer comprises forming a separating layer between two substrate portions.

23. The method according to claim 14, further comprising:
forming a third semiconductor layer over the second semiconductor layer;
applying a carrier material over the third semiconductor layer;
removing the first layer stack and the second semiconductor layer;
applying a second modification substrate over the third semiconductor layer, wherein a material of the second modification substrate has a thermal expansion coefficient which is different from that of the third semiconductor layer;
removing the carrier material thereby obtaining a second layer stack;
heating the second layer stack to a second growth temperature; and
growing a fourth semiconductor layer.

24. A workpiece comprising:
a first single-crystal semiconductor layer, wherein a material of the first semiconductor layer is Inₓ₁Al_{y1}Ga_{(i-x1-y1)}N, with 0≤x1≤1, 0≤y1≤1; and
a second single-crystal semiconductor layer, wherein the second single-crystal semiconductor layer is arranged over the first single-crystal semiconductor layer,
wherein a composition of the first single-crystal semiconductor layer differs from a composition of the second single-crystal semiconductor layer, and
wherein a material of the second semiconductor layer is Inₓ₂Al_{y2}Ga_{(1-x2-y2)}N, with xl≠x2, yl≠y2.

25. The workpiece of claim 24, further comprising a modification substrate over the first single-crystal semiconductor layer, wherein a material of the modification substrate has a thermal expansion coefficient which is different from that of the first single-crystal semiconductor layer.

26. A method for manufacturing a semiconductor device, the method comprising:
forming a first semiconductor layer over a growth substrate, wherein a material of the first semiconductor layer is Inₓ₁Al_{y1}Ga_{(1-x1-y1)}N, with 0≤xl≤1, 0≤yl≤1;
applying a modification substrate over the first semiconductor layer, wherein a material of the modification substrate has a thermal expansion coefficient which is different from that of the first semiconductor layer;
removing the growth substrate thereby obtaining a first layer stack;
heating the first layer stack to a growth temperature; and
growing a second semiconductor layer over a growth surface of the first semiconductor layer after heating the first layer stack.
